(19) United States
(12) Patent Application Publication
(10) Pub. No.: US 2017/0079142 A1
(43) Pub. Date: Mar. 16, 2017

(54) PRINTED CIRCUIT BOARD AND MANUFACTURING METHOD THEREOF

(71) Applicant: Samsung Electro-Mechanics Co., Ltd., Suwon-Si (KR)

(72) Inventors: Jae-Ean LEE, Busan (KR); Jung-Han LEE, Seoul (KR); Jin-Ho PARK, Seoul (KR); Jung-Hyun CHO, Busan (KR); Yong-Ho BAEK, Seoul (KR)

(73) Assignee: Samsung Electro-Mechanics Co., Ltd., Suwon-Si (KR)

(21) Appl. No.: 15/078,452

(22) Filed: Mar. 23, 2016

(30) Foreign Application Priority Data
Sep. 16, 2015 (KR) 10-2015-0131215

(51) Int. Cl. H05K 1/18; H05K 3/00; H05K 1/09; H05K 3/46; H05K 1/02; H05K 1/11

(52) U.S. Cl. CPC H05K 1/183; H05K 1/0298; H05K 1/113; H05K 1/09; H05K 3/4655; H05K 3/0023; H05K 3/005; H05K 2203/1377

(57) ABSTRACT

A printed circuit board and a manufacturing method thereof are provided. A printed circuit board may include a first insulating layer comprising a photosensitive material on a core layer, a second insulating layer comprising a material comprising a reinforcing material on the first insulating layer, and a cavity formed in the first insulating layer and the second insulating layer.

### CROSS REFERENCE TO RELATED APPLICATION(S)

This application claims the benefit under 35 USC §119(a) of Korean Patent Application No. 10-2015-0131215 filed on Sep. 16, 2015 in the Korean Intellectual Property Office, the entire disclosure of which is incorporated herein by reference for all purposes.

### BACKGROUND

Field

The following description relates to a printed circuit board and a method for manufacturing the same.

Description of Related Art

Various types of boards have been developed in response to demands for semiconductor packages with smaller sizes and higher performances. Recently, a cavity board technology has been also developed as a previous step of the embedding technology. Such a cavity board technology allows forming two-sided mounting boards from conventional single-sided mounting boards. When a cavity board is used, a cavity can be formed in one surface of a two-sided mounting board to mount a die or component. Such a cavity board is formed by using a dry film resist (DFR) barrier layer as a protection layer. When the cavity board is prepared using the DFR barrier layer, the DFR barrier layer should be designed not to be in contact with a prepreg to avoid DFR residues that may result when the DFR barrier layer and the prepreg react with each other. In addition, the prepreg can cause resin flow, which may require a solder resist layer to be formed to have a certain minimum thickness. For these reasons, a photolithography process may be used to prepare the cavity board in which a photoimageable dielectric material is used, instead of the prepreg.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to a general aspect, a printed circuit board may include a first insulating layer comprising a photosensitive material on a core layer, a second insulating layer comprising a material comprising a reinforcing material on the first insulating layer, and a cavity formed in the first insulating layer and the second insulating layer.

In an embodiment, the printed circuit board further includes a conductive pattern formed on the core layer in the cavity.

In an embodiment, the second insulating layer includes a prepreg having a copper foil laminated on one surface.

In an embodiment, the printed circuit board further includes a solder resist layer on the second insulating layer.

In an embodiment, the printed circuit board further includes a surface treatment layer on the conductive pattern.

According to a general aspect, a method for manufacturing a printed circuit board may include disposing a first insulating layer comprising a photosensitive material on a core layer, forming a first cavity in the first insulating layer; forming a second cavity to correspond to the first cavity in a second insulating layer formed of a material comprising a reinforcing material, and disposing the second insulating layer on the first insulating layer.

In an embodiment, the disposing the first insulating layer includes laminating the photosensitive material on the core layer.

In an embodiment, the disposing the second insulating layer comprises laminating the second insulating layer on the first insulating layer.

In an embodiment, the forming the first cavity includes photo-exposing and chemically removing portions of the first insulating layer.

In an embodiment, the method further includes laminating a protection layer configured to cover a conductive pattern inside the first cavity after disposing the first insulating layer on the core layer. The first cavity may expose the conductive pattern formed on the core layer.

In an embodiment, the method further includes removing the protection layer after disposing the second insulating layer on the first insulating layer.

In an embodiment, an upper surface height of the protection layer is equal to or less than that of the first insulating layer.

In an embodiment, the second insulating layer is a prepreg having a copper foil laminated on one surface.

In an embodiment, the forming the second cavity comprises punching a portion of the prepreg material.

In an embodiment, a portion of the second insulating layer is greater than an area of the first cavity.

In an embodiment, the portion of the second insulating layer greater than the area of the first cavity is punched is laminated.

In an embodiment, the method further includes forming a solder resist layer on the second insulating layer.

In an embodiment, the method further includes forming a surface treatment layer on the conductive pattern.

In another general aspect, a printed circuit board may include a first insulating layer disposed on a core layer, a second insulating layer disposed on the first insulating layer, and a cavity in the first insulating layer and the second insulating layer. The cavity exposes a conductive pattern present on the core layer, and is configured to enable an external chip to contact the conductive pattern.

In an embodiment, the first insulating layer comprises a photosensitive material that is non-reactive with dry film resist (DFR) film, and the second insulating layer comprises a reinforcing material.

Other features and aspects will be apparent from the following detailed description, the drawings, and the claims.

### BRIEF DESCRIPTION OF THE DRAWNIGS

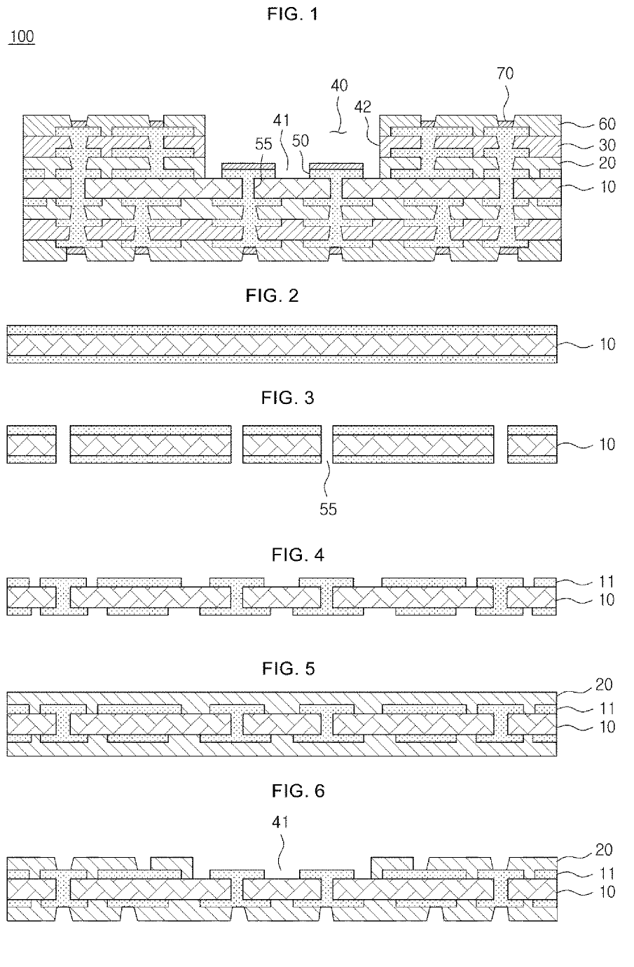

FIG. 1 illustrates a sectional view of a printed circuit board, in accordance with an embodiment.

FIG. 2 illustrates a sectional view of a printed circuit board being manufactured using a method for manufacturing the printed circuit board, in accordance with an embodiment.

FIG. 3 illustrates a sectional view of a printed circuit board being manufactured using a method for manufacturing the printed circuit board, in accordance with an embodiment.

FIG. 4 illustrates a sectional view of a printed circuit board being manufactured using a method for manufacturing the printed circuit board, in accordance with an embodiment.

FIG. 5 illustrates a sectional view of a printed circuit board being manufactured using a method for manufacturing the printed circuit board, in accordance with an embodiment.

FIG. 6 illustrates a sectional view of a printed circuit board being manufactured using a method for manufacturing the printed circuit board, in accordance with an embodiment.

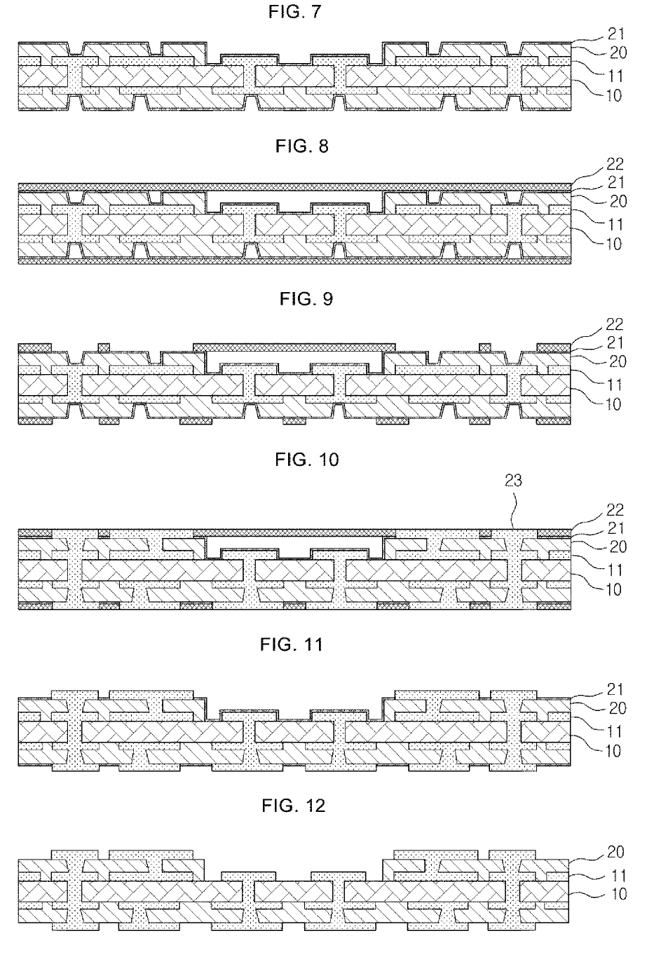

FIG. 7 illustrates a sectional view of a printed circuit board being manufactured using a method for manufacturing the printed circuit board, in accordance with an embodiment.

FIG. 8 illustrates a sectional view of a printed circuit board being manufactured using a method for manufacturing the printed circuit board, in accordance with an embodiment.

FIG. 9 illustrates a sectional view of a printed circuit board being manufactured using a method for manufacturing the printed circuit board, in accordance with an embodiment.

FIG. 10 illustrates a sectional view of a printed circuit board being manufactured using a method for manufacturing the printed circuit board, in accordance with an embodiment.

FIG. 11 illustrates a sectional view of a printed circuit board being manufactured using a method for manufacturing the printed circuit board, in accordance with an embodiment.

FIG. 12 illustrates a sectional view of a printed circuit board being manufactured using a method for manufacturing the printed circuit board, in accordance with an embodiment.

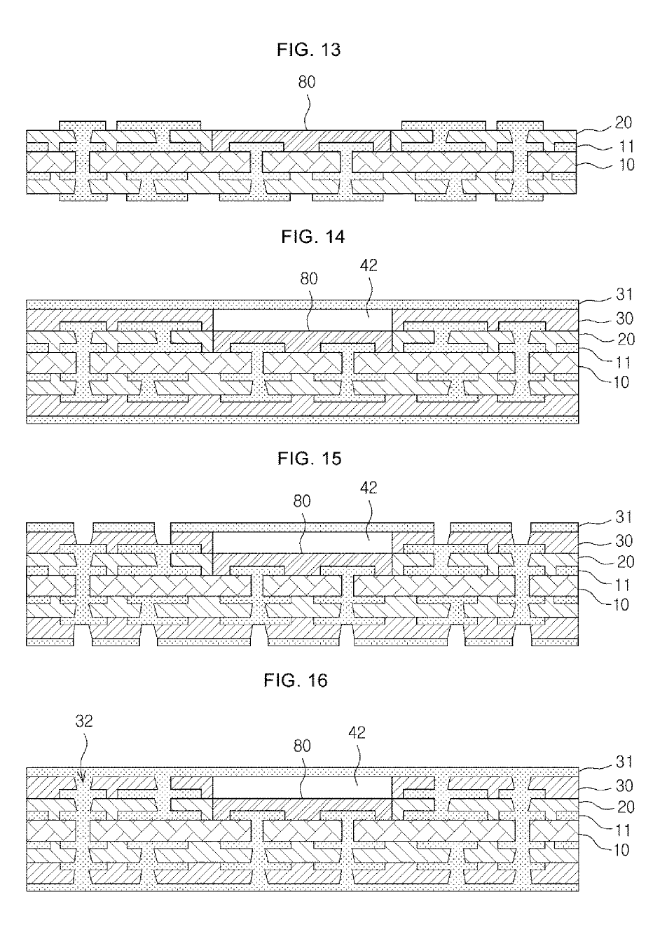

FIG. 13 illustrates a sectional view of a printed circuit board being manufactured using a method for manufacturing the printed circuit board, in accordance with an embodiment.

FIG. 14 illustrates a sectional view of a printed circuit board being manufactured using a method for manufacturing the printed circuit board, in accordance with an embodiment.

FIG. 15 illustrates a sectional view of a printed circuit board being manufactured using a method for manufacturing the printed circuit board, in accordance with an embodiment.

FIG. 16 illustrates a sectional view of a printed circuit board being manufactured using a method for manufacturing the printed circuit board, in accordance with an embodiment.

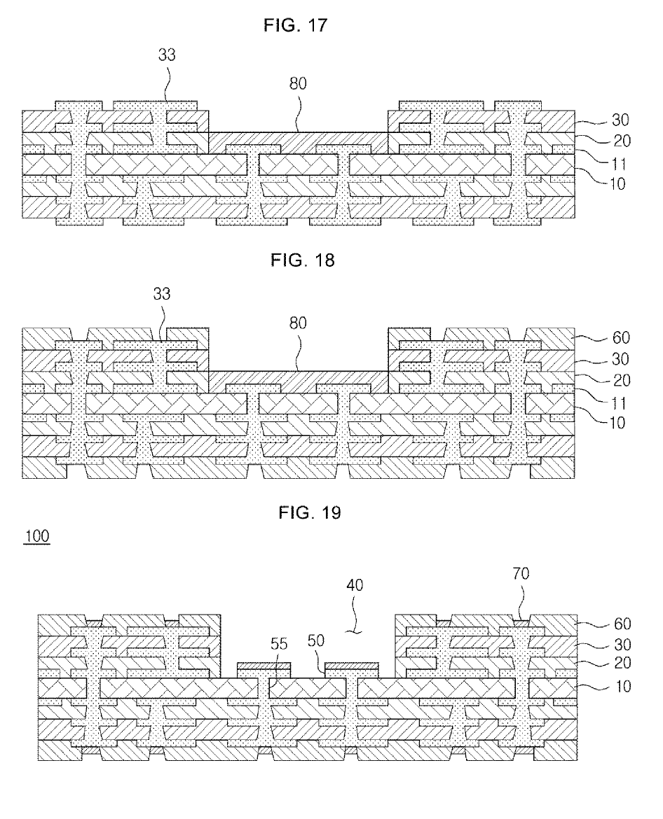

FIG. 17 illustrates a sectional view of a printed circuit board being manufactured using a method for manufacturing the printed circuit board, in accordance with an embodiment.

FIG. 18 illustrates a sectional view of a printed circuit board being manufactured using a method for manufacturing the printed circuit board, in accordance with an embodiment.

FIG. 19 illustrates a sectional view of a printed circuit board being manufactured using a method for manufacturing the printed circuit board, in accordance with an embodiment.

Throughout the drawings and the detailed description, unless otherwise described or provided, the same reference numerals refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure is thorough, complete, and conveys the full scope of the disclosure to one of ordinary skill in the art.

It will be understood that, although the terms “first,” “second,” “third,” “fourth” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. Similarly, when it is described that a method includes series of steps, a sequence of the steps is not a sequence in which the steps should be performed in the sequence, an arbitrary technical step may be omitted and/or another arbitrary step, which is not disclosed herein, may be added to the method.

The terms used in the description are intended to describe certain embodiments only, and shall by no means restrict the present disclosure. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

The terms used herein may be exchangeable to be operated in different directions than shown and described herein under an appropriate environment. It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Hereinafter, certain embodiments of the present disclosure will be described in detail with reference to the accompanying drawings.

FIG. 1 illustrates a cross-sectional view of an example printed circuit board.

Referring to FIG. 1, a printed circuit board 100 according to an example may include a core layer 10, a first insulating layer 20, a second insulating layer 30, a cavity 40, a conductive pattern 50, a solder resist layer 60, and a surface treatment layer 70.

Core layer 10 may be formed at the center of printed circuit board 100 to maintain stability against warpage problems of the board. Core layer 10 may be formed of materials such as, for example, silicon, glass, or ceramic which are used for copper clad lamination or interposer. However, the material for forming core layer 10 may not be limited thereto.

As shown in FIG. 1, conductive pattern 50 is formed on core layer 10. The conductive pattern may be formed of a suitable conducting material such as, for example, copper, gold, aluminum, or silver. A through hole 55 may be formed in core layer 10 to connect conductive pattern 50 formed on an upper surface and a lower surface of core layer 10.

At least one first insulating layer 20 is formed on the upper surface, the lower surface, or both upper and lower surface of core layer 10. In an embodiment, first insulating layer 20 is formed of a photosensitive material. For example, first insulating layer 20 may be formed of a photosensitive material including, but not limited to, a photosensitive polyhydroxystyrene (PHS), a photosensitive polybenzoxazole (PBO), a photosensitive polyimide (PI), a photosensitive benzocyclobutene (BCB), a photosensitive polysiloxane, a photosensitive epoxy, a novolac resin, or a combination thereof. In an embodiment, first insulating layer 20 formed of the photosensitive material is chosen to prevent DFR residues and other circuit-related defects. In other words, first insulating layer 20 is chosen to not react with a DFR film.

At least one second insulating layer 30 formed on the upper surface of first insulating layer 20. It will be understood that when second insulating layer 30 is formed on the upper surface of first insulating layer 20, second insulating layer 30 can be directly formed on first insulating layer 20, or one or more intervening layers may be present.

In an embodiment, second insulating layer 30 is formed of a non-photosensitive material such as a resin including, but not limited to, a reinforcing material such as a glass cloth or an inorganic filler. For example, second insulating layer 30 may be formed in a prepreg. In another embodiment, second insulating layer 30 is formed in a prepreg on which a copper foil is laminated to form circuit patterns. In such embodiments, the reinforcing material of second insulating layer 30 may provide warpage reduction effects.

Cavity 40 may be formed in first insulating layer 20 and second insulating layer 30. In some embodiments, cavity 40 includes a first cavity 41 included in first insulating layer 20 and a second cavity 42 included in second insulating layer 30. Here, first cavity 41 may be formed through exposing and developing processes.

In an embodiment, conductive pattern 50 is formed on the upper surface of core layer 10 inside cavity 40. In an embodiment, conductive pattern 50 is formed through a photolithography process. Particularly, conductive pattern 50 may be formed through a tenting process. Since conductive pattern 50 is formed inside cavity 40 of first insulating layer 20 and second insulating layer 30, chips may be mounted inside the cavity of first insulating layer 20 and second insulating layer 30, thereby reducing the height (thickness) of the assembled printed circuit board.

In an embodiment, solder resist layer 60 is formed on second insulating layer 30 to selectively expose conductive pattern 50. In such an embodiment, solder resist layer 60 may cover and protect the pattern to prevent any unintended connection which may be caused by a solder while mounting components. Solder resist layer 60 may, thus, function to prevent short, corrosion or contamination of the circuit pattern and protect the circuit of the printed circuit board from external impacts and chemicals.

In an embodiment, surface treatment layer 70 is formed on the upper surface of conductive pattern 50. For example, surface treatment layer 70 may be formed by an electroless nickel immersion gold (ENIG) method or an electroless nickel electroless palladium immersion gold (ENEPIG) method. In various embodiments, surface treatment layer 70 may include, but is not limited to, Au, Pd-p, Ni—P or Cu layer.

FIG. 2 to FIG. 19 illustrate an example of a method for manufacturing the printed circuit board of FIG. 1.

FIG. 2 to FIG. 4 illustrate an example of forming patterns on a core layer.

Referring to FIG. 2, a method for manufacturing a printed circuit board 100 according to an example includes obtaining a core layer 10 coated with a copper foil.

Referring to FIG. 3 the method further includes forming a through hole 55 in core layer 10 using any suitable technique. For example, through hole 55 may be formed using a laser drill. In an embodiment, the laser drill may include, without limitation, a carbon dioxide (CO₂) laser, a YAG laser, an excimer laser, or a combination thereof.

Referring to FIG. 4, a circuit pattern 11 is formed on core layer 10 using a suitable technique. For example, circuit pattern 11 may be formed through a photolithography process. Particularly, circuit pattern 11 may be formed through a tenting process. In some embodiments, the tenting process is a subtractive etching process. In such embodiments, an etching resist is formed on vias in order to avoid etching the vias during the etching process.

FIG. 5 to FIG. 12 illustrate an example of forming patterns on first insulating layer 20.

FIG. 5 and FIG. 6, illustrate laminating a first insulating layer 20 formed of a photosensitive material on the upper surface of core layer 10 and forming a first cavity 41 in the upper surface of first insulating layer 20.

For example, first cavity 41 may be formed using photolithography techniques. The photosensitive material is first exposed to ultraviolet light through a suitable photomask, and then chemically developed to remove the exposed (positive resist) or unexposed (negative resist) portions of the photosensitive material. In some embodiment, first insulating layer 20 is formed of a positive-type photosensitive material. The photopolymer bonds of the positive-type photosensitive material in the exposed portion are broken during the exposing process. The exposed parts of the photopolymer are then removed with the developing process. On the other hand, in other embodiments, first insulating layer 20 is formed of a negative-type photosensitive material. The molecules of the negative-type photosensitive material in the exposed portion undergo photo-polymerization. Following a curing process, the exposed portions of the negative-type photosensitive material are hardened. The unhardened parts are then removed with the developing process. In some embodiments, a portion of first insulating layer 20 is formed of a positive-type photosensitive material, and a remaining portion is formed of a negative-type photosensitive material.

FIG. 7 illustrates a plating layer 21 formed on the upper surface of first insulating layer 20. In an embodiment, plating layer 21 is formed using an electroless Cu plating process. The plating process may be conducted using any conductive metal in addition to, or instead of Cu.

FIG. 8 illustrates a film 22 formed on the upper surface of first insulating layer 20 using laminating operation. In an embodiment, the film 22 is a DFR film.

FIG. 9 illustrates the results of photo exposure (through a suitable photo mask) and development of the resist layer on film 22.

FIG. 10 illustrates a circuit pattern 23 formed on the upper surface of first insulating layer 20. The circuit pattern 23 may be formed through a tenting process, a semi-additive process (SAP), or a modified semi-additive process (MSAP), which is typically used to form circuit patterns on circuit boards. In an embodiment, circuit pattern 23 is formed through an electrolytic Cu plating process.

FIG. 11 illustrates the results of stripping operation on film 22 in a method of manufacturing a printed circuit board, in accordance with an embodiment.

FIG. 12 illustrates a printed circuit board following removal of plating layer 21 in a method of manufacturing a printed circuit board, in accordance with an embodiment. Plating layer 21 may be removed by a flash etching process. The flash etching process may selectively remove plating layer 21 formed through electroless Cu plating using structural differences such as, for example, Cu particle size and Cu particle density between copper layer(s) obtained by the electroless plating and copper layer(s) obtained by electrolytic plating.

FIG. 13 to FIG. 17 illustrate the printed circuit board following laminating a second insulating layer and forming a pattern thereon in a method of manufacturing a printed circuit board, in accordance with an embodiment.

Referring to FIG. 13, a protection layer 80 may be laminated on core layer 10 following the removal of plating layer 21. In an embodiment, protection layer 80 is a DFR film. The thickness of protection layer 80 may be equal to or less than that of first insulating layer 20. Because in such a process, protection layer 80 and second insulating layer 30 are not in contact with each other, DFR residues and other circuit-related defects are avoided.

FIG. 14 illustrates the cross-section of a printed circuit board following a lamination operation for disposing second insulating layer 30 in a method of manufacturing a printed circuit board, in accordance with an embodiment. The second insulating layer 30 may be a prepreg on which a copper foil can be laminated.

In some embodiments, second insulating layer 30 of which the prepreg material is punched is laminated. In some embodiments, second insulating layer 30 of which punched width is wider than that of protection layer 80 is laminated. Because prepreg has a low flow, in embodiments where second insulating layer 30 is a prepreg, even though second insulating layer 30 of which punched width is wider than that of protection layer 80 is laminated, width of insulating layer 30 can be corresponded to the width of the cavity 40.

FIG. 15 illustrates the printed circuit board following etching operation on copper foil 31 in a method of manufacturing a printed circuit board, in accordance with an embodiment. In an embodiment, the etching operation includes, or is followed by patterning and drilling second insulating layer 30 by a laser drill process.

FIG. 16 illustrates the printed circuit board following forming a via 32 in second insulating layer 30 in a method of manufacturing a printed circuit board, in accordance with an embodiment. For example, via 32 is formed through a Cu plating process. Via 32 may connect circuit patterns 33 formed on the upper surface and the lower surface of second insulating layer 30.

FIG. 17 illustrates the printed circuit board following forming circuit pattern 33 on second insulating layer 30 in a method of manufacturing a printed circuit board, in accordance with an embodiment. Circuit pattern 33 may be formed using any suitable process such as, for example, a photolithography process. In some embodiments, circuit pattern 33 is formed through a tenting process.

FIG. 18 and FIG. 19 illustrate examples of surface-treating the printed circuit board in which first insulating layer 20 and second insulating layer 30 are laminated.

a. FIG. 18 illustrates the printed circuit board following laminating a solder resist layer 60 on second insulating layer 30 in a method of manufacturing a printed circuit board, in accordance with an embodiment.

FIG. 19 illustrates the printed circuit board following stripping protection layer 80 and laminating surface treatment layer 70 to protect circuit pattern 33 and conductive pattern 50 in a method of manufacturing a printed circuit board, in accordance with an embodiment. For example, surface treatment layer 70 may be formed by an electroless nickel immersion gold (ENIG) method or an electroless nickel electroless palladium immersion gold (ENEPIG) method.

The printed circuit board according to an example may not cause DFR residues and other circuit-related defects because first insulating layer 20 is formed of the material which does not react with protection layer 80.

The printed circuit board according to an example may provide warpage reduction effects because second insulating layer 30 is formed of a material with high rigidity to surround first insulating layer 20.

The printed circuit board according to an example may reduce the entire thickness by forming cavity 40 inside first insulating layer 20 and second insulating layer 30.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. For example, suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board, comprising:
a first insulating layer comprising a photosensitive material on a core layer;
a second insulating layer comprising a reinforcing material on the first insulating layer; and
a cavity formed in the first insulating layer and the second insulating layer.

2. The printed circuit board of claim 1, further comprising a conductive pattern formed on the core layer in the cavity.

3. The printed circuit board of claim 1, wherein the second insulating layer is a prepreg having a copper foil laminated on one surface.

4. The printed circuit board of claim 1, further comprising a solder resist layer on the second insulating layer.

5. The printed circuit board of claim 1, further comprising a surface treatment layer on the conductive pattern.

6. A method for manufacturing a printed circuit board, the method comprising:
disposing a first insulating layer comprising a photosensitive material on a core layer;
forming a first cavity in the first insulating layer;
forming a second cavity to correspond to the first cavity in a second insulating layer formed of a material comprising a reinforcing material; and
disposing the second insulating layer on the first insulating layer.

7. The method of claim 6, wherein the disposing the first insulating layer comprises laminating the photosensitive material on the core layer.

8. The method of claim 6, wherein the disposing the second insulating layer comprises laminating the second insulating layer on the first insulating layer.

9. The method of claim 6, wherein the forming the first cavity comprises photo-exposing and chemically removing portions of the first insulating layer.

10. The method of claim 6, further comprising laminating a protection layer configured to cover a conductive pattern inside the first cavity after disposing the first insulating layer on the core layer, wherein the first cavity exposes the conductive pattern formed on the core layer.

11. The method of claim 10, further comprising removing the protection layer after disposing the second insulating layer on the first insulating layer.

12. The method of claim 10, wherein an upper surface height of the protection layer is equal to or less than that of the first insulating layer.

13. The method of claim 6, wherein the second insulating layer is a prepreg having a copper foil laminated on one surface.

14. The method of claim 13, wherein the forming the second cavity comprises punching a portion of the prepreg material.

15. The method of claim 6, wherein a portion of the second insulating layer is greater than an area of the first cavity.

16. The method of claim 15, wherein the portion of the second insulating layer greater than the area of the first cavity is punched is laminated.

17. The method of claim 6, further comprising forming a solder resist layer on the second insulating layer.

18. The method of claim 10, further comprising forming a surface treatment layer on the conductive pattern.

19. A printed circuit board, comprising:
a first insulating layer disposed on a core layer;
a second insulating layer disposed on the first insulating layer; and
a cavity in the first insulating layer and the second insulating layer, the cavity exposing a conductive pattern present on the core layer,
wherein the cavity is configured to enable an external chip to contact the conductive pattern.

20. The printed circuit board of claim 19, wherein the first insulating layer comprises a photosensitive material that is non-reactive with dry film resist (DFR) film, and the second insulating layer comprises a reinforcing material.
